(19) United States
(12) Patent Application Publication
(10) Pub. No.: US 2008/0006853 A1
(43) Pub. Date: Jan. 10, 2008

(54) Schottky Electrode of Nitride Semiconductor Device and Process for Production Thereof

(75) Inventors: Hironobu Miyamoto, Minato-ku (JP); Tatsuo Nakayama, Minato-ku (JP); Yuji Ando, Minato-ku (JP); Yasuhiro Okamoto, Minato-ku (JP); Masaaki Kuzuhara, Minato-ku (JP); Takashi Inoue, Minato-ku (JP); Koji Hataya, Chiyoda-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Tokyo (JP)

(21) Appl. No.: 11/571,816

(22) PCT Filed: Jul. 8, 2005
(86) PCT No.: PCT/JP05/12669

§ 371 Date: Sep. 27, 2007

(30) Foreign Application Priority Data
Jul. 8, 2004 (JP) 2004-201628

(51) Int. Cl. H01L 29/47; H01L 21/283; H01L 29/812

(52) U.S. Cl. 257/280; 257/473; 438/575; 257/E29.149; 257/E29.317; 257/E21.173; 257/E21.186

(57) ABSTRACT

The present invention provides a Schottky electrode for a nitride semiconductor device having a high barrier height, a low leak current performance and a low resistance and being thermally stable, and a process for production thereof. The Schottky electrode for a nitride semiconductor has a layered structure that comprises a copper (Cu) layer being in contact with the nitride semiconductor and a first electrode material layer formed on the copper (Cu) layer as an upper layer. As the first electrode material, a metal material which has a thermal expansion coefficient smaller than the thermal expansion coefficient of copper (Cu) and starts to undergo a solid phase reaction with copper (Cu) at a temperature of 400° C. or higher is employed.

### TECHNICAL FIELD

The present invention relates to a Schottky electrode for a nitride semiconductor device and a process for production thereof, and relates particularly to a Schottky electrode for a nitride semiconductor device which has a high barrier height, a low leak current performance and a low resistance and being thermally stable, and a process for production thereof.

### BACKGROUND ART

In a nitride semiconductor electric field effect transistor, a metal multilayer film structure including Ni, Pt and Pd has been previously used as a Schottky electrode material (JP 10-223901 A, JP 11-219919 A and JP 2004-087740 A), but there has been such a problem that a Schottky gate electrode made therewith exhibits such a low barrier height of about 0.9 to 1.0 eV and a large reverse leak current.

As an approach for solving the problem, there has been proposed use of copper (Cu) as a Schottky electrode material. According to TWHM 2003 proceedings (Topical Workshop on Heterostructure Microelectronics 2003, page 64), it has been reported that by forming a Schottky electrode with copper (Cu) film having a thickness of 200 nm, the barrier height thereof is increased by 0.1 to 0.2 eV and the reverse leak current is reduced by an order of about 2 digits, in comparison with the values reported for conventional ones.

### DISCLOSURE OF THE INVENTION

Problem to be Solved by the Invention

However, the technique described above can increase the Schottky barrier height to 1.1 eV, but it is insufficient for setting a gate bias of a nitride semiconductor electric field effect transistor in a high level when the Schottky electrode is used as a gate electrode of the nitride semiconductor electric field effect transistor, and thus a higher Schottky barrier height is desired. Further, for using it as the gate electrode thereof, there still remains a problem that further reduction of a resistance is required.

The present invention has been made in view of such problems, and its object is to provide such a Schottky electrode for a nitride semiconductor device that is thermally stable and have a low resistance value, a higher Schottky barrier height and a low leak current in reverse bias when used as a gate electrode of a nitride semiconductor electric field effect transistor, and a process for production thereof.

Means for Solving Problem

A Schottky electrode for a nitride semiconductor device according to the present invention is characterized in that:
the Schottky electrode has a layered structure that comprises a copper (Cu) layer being in contact with a nitride semiconductor and a first electrode material layer formed on said copper (Cu) layer as an upper layer thereof, and
the temperature at which said first electrode material starts to undergo a solid phase reaction with copper (Cu) is 400° C. or higher.

The Schottky electrode for a nitride semiconductor device according to the present invention may have further such a feature that the thermal expansion coefficient of said first electrode material is smaller than the thermal expansion coefficient of copper (Cu).

The Schottky electrode for a nitride semiconductor device according to the present invention may have such a feature that a second electrode material layer is further formed on said first electrode material layer,
the thermal expansion coefficients of said first electrode material and second electrode material are smaller than the thermal expansion coefficient of copper (Cu), or an internal stress caused by thermal expansion in said first electrode material layer and second electrode material layer is reduced by plastic deformation thereof, and
further, the resistivity of said second electrode material is lower than the resistivity of the first electrode material.

The Schottky electrode for a nitride semiconductor device according to the present invention may have such a feature that the first electrode material is molybdenum, tungsten, niobium, palladium, platinum or titanium.

The Schottky electrode for a nitride semiconductor device according to the present invention may have such a feature that the second electrode material is gold or aluminum.

A nitride semiconductor electric field effect transistor according to the present invention is characterized in that the Schottky electrode for a nitride semiconductor device mentioned above is used as a gate electrode thereof.

A process for production of a Schottky electrode for a nitride semiconductor device according to the present invention is characterized by comprising:
a step of forming a metal layer in which at least a copper (Cu) layer is formed on a nitride semiconductor layer; and
a step of carrying out a heat treatment at a temperature of 300° C. or higher and 650° C. or lower.

The process for production of a Schottky electrode for a nitride semiconductor device according to the present invention may have such a feature that said step of forming a metal layer comprises the sub-steps of:
forming the copper (Cu) layer; and
forming a first electrode material layer.

The process for production of a Schottky electrode for a nitride semiconductor device according to the present invention may have such a feature that said metal layer forming step comprises the sub-steps of:
forming the copper (Cu) layer;
forming a first electrode material layer; and
forming a second electrode material layer.

Effect of the Invention

The present invention provides a Schottky electrode for a nitride semiconductor which has a layered structure that comprises a copper (Cu) layer being in contact with the nitride semiconductor and a first electrode material layer formed on the copper (Cu) layer as an upper layer thereof, wherein such material that has a thermal expansion coefficient smaller than that of Cu and such a threshold temperature at which it starts to undergo a solid phase reaction with Cu being 400° C. or higher is selected as the first electrode material.

As the thermal expansion coefficient of the first electrode material is smaller than the thermal expansion coefficient of Cu, it has such an effect of suppressing a piezoelectric charge generated by deformation of the nitride semiconductor and of inhibiting a decrease in a Schottky barrier height resulting from generation of the piezoelectric charge. Furthermore, a solid phase reaction of the first electrode material with Cu is hardly induced by a heat treatment at 300° C. or higher and 650° C. or lower, and thus, it also has an effect of maintaining a fine electrode shape.

### BRIEF DESCRIPTION OF THE DRAWINGS

FIG. 1 is a sectional view showing the structure of a Schottky electrode for a nitride semiconductor device in the first embodiment according to the present invention;

FIG. 2 is a sectional view showing the structure of a Schottky electrode for a nitride semiconductor device in the second embodiment according to the present invention;

FIG. 3 is a sectional view showing the structure of a Schottky electrode of a nitride semiconductor device in the third embodiment according to the present invention; and

FIG. 4 is a sectional view schematically showing the construction of a nitride semiconductor device which employs the Schottky electrode according to the present invention.

### DESCRIPTION OF THE SYMBOLS

1 nitride semiconductor
2 copper (Cu)
3 first electrode material
5 second electrode material
6 nitride semiconductor operation layer
7 source electrode
8 gate electrode
9 drain electrode

### BEST MODE FOR CARRYING OUT THE INVENTION

Embodiments of the present invention will be explained hereinafter with reference to the drawings.

### First Embodiment

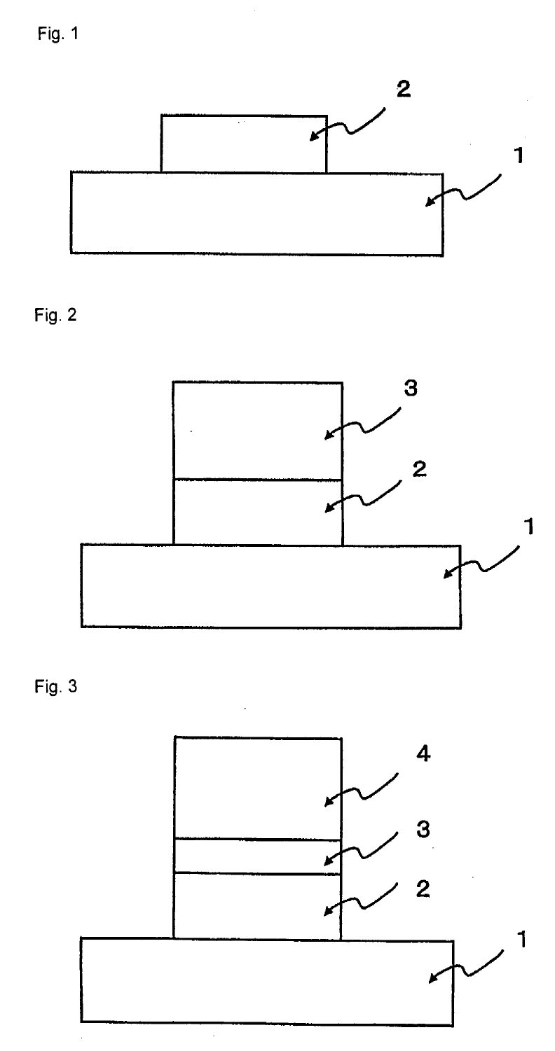

One embodiment according to the present invention is illustrated in FIG. 1. FIG. 1 shows a sectional view of a Schottky electrode for a nitride semiconductor device as the first embodiment according to the present invention.

As shown in FIG. 1, copper (Cu) layer 2 is formed on the surface of a nitride semiconductor 1. By increasing the thickness of the copper (Cu) layer 2 formed therefor, the gate resistance can be reduced, whereby a high-output transistor operating at a high frequency can be realized. Further, it is confirmed that a heat treatment at such a temperature as 300° C. or 400° C. in the production process of the element has the effect of increasing a barrier height and reducing a gate leak current.

### EXAMPLE 1

This embodiment will be explained below by referring to a specific example. As a nitride semiconductor layer 1, an AlN buffer layer having a thickness of 4 nm and an n type GaN layer having a donor concentration of 10¹⁷ atoms·cm⁻³ and a thickness of 2000 nm were formed on a high-resistance SiC substrate. Furthermore, Ti and Al were successively deposited thereon as an ohmic electrode for the nitride semiconductor. Thereafter, it was subjected to a heat treatment at 650° C. in a nitrogen atmosphere to form an ohmic contact.

After that, copper (Cu) 2 was deposited in a thickness of 200 nm or 400 nm and then lifted off to form a Schottky electrode according to the present invention. The Schottky electrode could also be formed by means of sputtering. Furthermore, for comparison, samples of conventional type in which Ni/Au, Pt/Au or Pd/Au was employed as electrode material were prepared. Table 1 shows the results measured for the samples.

[Table 1]

TABLE 1

| | Electrode materials | Barrier | | |
|---|---|---|---|---|
| | (heat treatment | heights | | Thickness |
| Experiments | temperature) | (eV) | n values | (nm) |
| 1 | Ni/Au | 0.95 | 1.23 | 15/400 |
| 2 | Pt/Au | 1.00 | 1.23 | 15/400 |
| 3 | Pd/Au | 0.94 | 1.23 | 15/400 |
| 4 | Cu | 1.10 | 1.16 | 200 |
| 5 | Cu (300° C.) | 1.24 | 1.16 | 200 |
| 6 | Cu (400° C.) | 1.29 | 1.16 | 200 |
| 7 | Cu | 1.10 | 1.16 | 400 |
| 8 | Cu (300° C.) | 1.10 | 1.16 | 400 |
| 9 | Cu (400° C.) | 1.00 | 1.20 | 400 |

Electrode material used for formation of the Schottky electrode and its heat treatment temperature, barrier height of the Schottky diode which was estimated based on its current/voltage characteristics in forward bias, n value (ideality factor: in ideal case n=1) that is a constant representing the current/voltage characteristics in forward bias, and the thickness of the electrode material layer formed are summarized in Table 1. When copper (Cu) is employed as an electrode material, the barrier heights measured for the samples having the thickness of 200 nm and of 400 nm are both as high as 1.1 eV. Further, in the case of the diode employing the copper (Cu) layer with the thickness of 200 nm, by heat-treating the Schottky diode at 300° C. or 400° C., the barrier height was further increased from 1.1 eV, i.e. the value measured before the heat treatment, to 1.24 eV or 1.29 eV, respectively.

In contrast, in the case of the diode employing the copper (Cu) layer with the thickness of 200 nm, when the Schottky diode was heat-treated at 300° C. or 400° C., the barrier height was not changed from 1.1 eV, i.e. the value before the heat treatment, or decreased to 1.0 eV, and thus an effect due to the heat treatment was not obtained. It may be reasoned that this is because as the thickness is thicker, such a phenomenon specific to a nitride semiconductor that piezoelectric charges are generated due to strain on the nitride semiconductor becomes more significant, and thus such reduction in the Schottky barrier height results from the generation of the piezoelectric charge.

In this example, in the case where copper (Cu) was employed as an electrode material and its thickness was 200 nm, such a result that the barrier height further increased from 1.1 eV, i.e. the value before the heat treatment, to 1.24 eV or 1.29 eV was attained by heat treatment of the Schottky diode at 300° C. or 400° C., and so a Schottky electrode having a high barrier height was thus obtained. However, since reduction in the Schottky barrier height is induced by generation of a piezoelectric charge when the thickness is increased, there is a limit to the thickness.

For the heat treatment for increasing the barrier height, the temperature is 300° C. or higher, and it is preferable to set such an upper limit to the temperature that it is set at 650° C. or lower, which is corresponding to a temperature for forming the ohmic contact in the production process.

### Second Embodiment

The second embodiment according to the present invention is illustrated in FIG. 2. FIG. 2 shows a sectional structure view of the second embodiment. This embodiment is a Schottky electrode which has a high barrier height, and allows the thickness to be increased so as to have a low resistance value.

A copper (Cu) 2 layer having a thickness of 200 nm is formed on the surface of a nitride semiconductor 1, and then, as an upper layer thereof, a molybdenum (Mo) layer is formed as a layer of a first electrode material 3. If this structure is used, a total thickness of the metal film formed can be thicker by means of a layered structure in which molybdenum (Mo) layer is formed as the upper layer, and therefore a gate resistance can be reduced, thus making it possible to realize a high-output transistor operating at a high frequency. Further, it has been found in test process for producing the element that a heat treatment at 300° C. to 400° C. has a similar effect of improving the barrier height and reducing the gate leak current to that observed for the case of use of the copper (Cu) single layer having a thickness of 200 nm.

It may be reasoned that this is because such a phenomenon specific to a nitride semiconductor that piezoelectric charges are generated due to strain on the nitride semiconductor is suppressed by using Mo having a thermal expansion coefficient smaller than that of copper (Cu), and thereby such reduction in the Schottky barrier height resulting from the generation of the piezoelectric charge is also prevented. Furthermore, as the temperature at which Mo undergoes a solid phase reaction with Cu is 1000° C. or higher, such a solid phase reaction is hardly caused by a heat treatment at 300 to 400° C., and so it has an effect of well maintaining its fine electrode shape.

The first electrode material 3 is required to have a thermal coefficient smaller than that of copper (Cu) and be free from any solid phase reaction with copper (Cu) in a heat treatment at 300° C. or higher, and it is desirable that the temperature at which it undergoes the solid phase reaction is 400° C. or higher. Therefore, in this embodiment, explanation is made for such a mode in which Mo is used as a first electrode material, but the temperature at which Nb and W undergo a solid phase reaction with Cu is 1000° C. or higher, and thus, they may have a very similar effect. Furthermore, the temperature at which Pd, Pt and Ti, which are all vacuum deposited more easily than Mo, W and Nb, undergo a solid phase reaction with Cu is 500° C. or higher, and so these metals have a similar effect.

When the aforementioned metal, which shows the temperature at which it undergoes the solid phase reaction is 400° C. or higher, is deposited in layered shape as the first electrode material layer, and is subjected to a heat treatment, it is preferable that the temperature for the heat treatment is selected within such a range that it is at least 300° C. or higher but no higher than a temperature (solid phase reaction temperature) at which said metal undergoes a solid phase reaction with copper (Cu). In this connection, when the heat treatment temperature is set to a temperature higher than the temperature (solid phase reaction temperature) at which the metal undergoes a solid phase reaction with copper (Cu), it is preferable that the heat treatment time be selected within a range of several tens of seconds or shorter.

If such a structure is used, in which a metal material, which shows the temperature at which it undergoes the solid phase reaction is lower than 400° C., for instance Al (solid phase reaction temperature: 300° C.), Au (solid phase reaction temperature: 240° C.) or Ni (solid phase reaction temperature: 150° C.), is deposited in layered shape as the first electrode material layer 3, the total thickness of metal layers for the gate electrode increases. Accordingly, the gate resistance is also reduced, thus making it possible to realize a high-output transistor operating at a high frequency. On the other hand, it has been found in test process for producing the element that when a heat treatment is carried out at 300 to 400° C., an alloy formation reaction with copper (Cu) having a thickness of 200 nm occurs, and the morphology of the gate electrode is so disordered to fail in transistor operation. Accordingly, in such a structure is used, in which a metal material, which shows the temperature at which it undergoes the solid phase reaction is lower than 400° C. is deposited in layered shape as the first electrode material layer 3, such an effect of improving the barrier height and reducing a gate leak current can be by no means achieved by the heat treatment.

### EXAMPLE 2

This embodiment will be explained below by referring to a specific example. As a nitride semiconductor layer 1, an AlN buffer layer having a thickness of 4 nm and an n type GaN layer having a donor concentration of 10¹⁷ atoms·cm⁻³ and a thickness of 2000 nm were formed on a high-resistance SiC substrate. Furthermore, Ti and Al were successively vacuum deposited as an ohmic electrode for the nitride semiconductor. Thereafter, a heat treatment was carried out at 650° C. in a nitrogen atmosphere to form an ohmic contact.

After that, copper (Cu) 2 was vacuum deposited in a thickness of 200 nm, and molybdenum (Mo) was subsequently deposited in a thickness of 300 nm by an electron beam deposition, and then lifted off to form a Schottky electrode according to the present invention. The Schottky electrode could also be formed by means of sputtering. The barrier height was estimated based on its current/voltage characteristics of the Schottky diode in forward bias. The results are summarized in Table 2.

[Table 2]

TABLE 2

| | Electrode materials | Barrier | | |
|---|---|---|---|---|
| | (heat treatment | heights | | Thickness |
| Experiments | temperature) | (eV) | n values | (nm) |
| 10 | Cu/Mo | 1.10 | 1.16 | 200/300 |
| 11 | Cu/Mo (300° C.) | 1.24 | 1.16 | 200/300 |
| 12 | Cu/Mo (400° C.) | 1.29 | 1.16 | 200/300 |

By heat-treating the Schottky diode at 300° C. or 400° C., the barrier height was further increased from 1.1 eV, i.e. the value measured before the heat treatment, to 1.24 eV or 1.29 eV, respectively. The Schottky electrode was formed thickly with copper (Cu) layer in a thickness of 200 nm and molybdenum (Mo) layer in a thickness of 300 nm, but as for the barrier height, the same effect as that observed for the thin Cu single layer having a thickness of 200 nm was maintained in this case. A decrease in the barrier height resulting from a heat treatment, which was a problem found out in the case of using the Cu single layer having an increased thickness of 400 nm for reducing the resistance of the electrode, did not occur in this case. A Schottky electrode having a high barrier height and a low resistance was obtained by forming the Schottky electrode thickly with copper (Cu) layer in a thickness of 200 nm and molybdenum (Mo) layer in a thickness of 300 nm.

In the layered structure in which the first electrode material layer is formed on the copper (Cu) layer as the upper layer, it is preferable that the thickness do of copper (Cu) layer used as a lower layer is selected to be no thinner than 10 nm, which is a minimum thickness allowing formation of a desired gate electrode pattern and deposition in layer shape, but the thickness is selected to be within such a thickness range causing no peeling off, particularly range of 200 nm or less in terms of a film stress. Furthermore, the thickness d₁ of the first electrode material 3 to be layered thereon is required to meet the requirement of d₀≦d₁ if considering a difference in the thermal expansion coefficient between the nitride semiconductor and the first electrode material and copper (Cu). A metal material used as the first electrode material 3, which has a thermal expansion coefficient in an order almost same as the thermal expansion coefficient of the nitride semiconductor, is deposited generally at a low rate. The thickness d, of the first electrode material layer 3 for which such a metal material having a low deposition rate is employed is preferably selected to be in a range of 300 nm or thinner in terms of mass productivity.

Further, when tungsten (W) and niobium (Nb) were used in place of molybdenum (Mo) as the first electrode material 3, a similar effect was obtained.

For Schottky diodes using these three metals, performances were by no means deteriorated by heat treatment at 600° C. For palladium (Pd), platinum (Pt) or titanium (Ti) which are easily deposited by electron beam deposition, a similar effect was obtained by a heat treatment at 300° C. or 400° C.

For the heat treatment for increasing the barrier height, the temperature is to be 300° C. or higher, and it is preferable to set such an upper limit to the temperature that it is set at 650° C. or lower, which is lower than the temperature at which a solid phase reaction with Cu occurs and is corresponding to a temperature for forming the ohmic contact in the production process. Accordingly, it is preferable that for the heat treatment for improving the barrier height, the temperature is set to be 300° C. or higher and 650° C. or lower.

When the aforementioned metal, which shows the temperature at which it undergoes the solid phase reaction is 400° C. or higher, is deposited in layered shape as the first electrode material layer, it is preferable that the heat treatment time be selected within a range of several tens of seconds or shorter in such a case where the temperature for the heat treatment is selected, for instance within such a range of 300° C. or higher but no higher than 650° C., but to a temperature range higher than the temperature (solid phase reaction temperature) at which the metal undergoes a solid phase reaction with copper (Cu).

### EXAMPLE 3

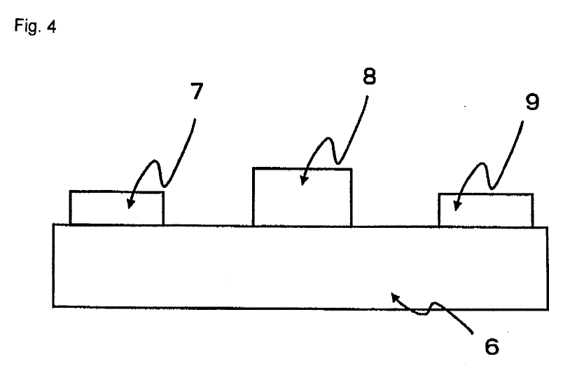

A nitride semiconductor electric field effect transistor using the Schottky electrode according to this embodiment as a gate electrode 8 is illustrated in FIG. 4. As a nitride semiconductor operation layer 6, an AlN buffer layer having a thickness of 4 nm, an undoped GaN layer having a thickness of 2000 nm and an AlGaN layer (Al composition ratio: 0.25, thickness: 30 nm) were formed on a high-resistance SiC substrate.

As a source electrode 7 and a drain electrode 9, Ti and Al were successively vacuum deposited. Thereafter, a heat treatment was carried out at 650° C. in a nitrogen atmosphere to form an ohmic contact. After that, copper (Cu) was vacuum deposited in a thickness of 200 nm, and molybdenum (Mo) was vacuum deposited in a thickness of 300 nm as a first electrode material and lifted off to form a gate electrode 8 according to the present invention.

By using the Schottky electrode as the gate electrode 8, an electric field effect transistor having a low gate resistance because of the increased thickness of the electrode and having a reduced reverse leak current could be formed. A high gain of 20 dB and a high output density of 10 W/mm (per gate width) could be obtained with a 60 V operation at an operation frequency of 20 GHz by a high-output device having a gate length of 1 micron and a gate width of 1 mm.

### Third Embodiment

Referring to FIG. 3, a sectional view of a nitride semiconductor Schottky electrode is shown as the third embodiment according to the present invention. This embodiment is a Schottky electrode allowing the thickness to be increased and having a low resistance value.

A layered structure comprising copper (Cu) layer 2 having a thickness of 200 nm, molybdenum (Mo) layer as a first electrode material layer 3 and gold (Au) layer as a second electrode material layer 4 as an upper layer thereof is formed on the surface of a nitride semiconductor 1. If this structure is used, owing to the structure in which the layers of molybdenum (Mo) and Au having a resistivity lower than that of Mo are formed in series as an upper layer, the gate resistance can be further reduced compared to those for the first and second embodiments, thus making it possible to realize a high-output transistor operating at a higher frequency.

As for the layered structure of copper (Cu) 2/the first electrode material 3/the second electrode material 4, if the thickness d₀ and resistivity ρ₀ of copper (Cu) 2, the thickness d₁ and resistivity ρ₁ of the first electrode material 3, and the thickness d₂ and resistivity ρ₂ of the second electrode material 4 are used, the sheet resistance ρₛₕₑₑₜ₃ of this layered structure is given by (1/ρₛₕₑₑₜ₃)=(d₀/ρ₀)+(d₁/ρ₁)+(d₂/ρ₂). The sheet resistance ρₛₕₑₑₜ₂ for the layered structure of copper (Cu) 2/the first electrode material 3 is given by (1/ρₛₕₑₑₜ₃)=(d₀/ρ₀)+(d₁/ρ₂). The effect of reducing the gate resistance by providing the second electrode material layer 4 becomes more noticeable in such a case where (d₂/ρ₂)≧{(d₀/ρ₀)+(d₁/ρ₁)}, or at least (d₂/ρ₂)≧(d₁/ρ₁). For fabricating a gate electrode having a dimension of around 1 μm with high controllability, it is 2 0 preferable that the total thickness of the layered structure (d₀+d₁+d₂) is selected to be in a range corresponding to the aforementioned dimension of the gate electrode. Therefore, the thickness d₁ of the first electrode material layer 3 and the thickness d₂ of the second electrode material layer 4 are preferably selected so that at least the requirement of (ρ₂/ρ₁)·d₁≦d₂≦1 μm is met.

Furthermore, it has been found in test process for producing the element that a heat treatment at 300 to 400° C. has the effect of improving the barrier height and reducing a gate leak current, in similar to the case of using the copper (Cu) single layer having a thickness of 200 nm. It may be reasoned that this is because such a phenomenon specific to a nitride semiconductor that piezoelectric charges are generated due to strain on the nitride semiconductor is suppressed by using Mo having a thermal expansion coefficient smaller than that of copper (Cu) and using Au as the second electrode material in which strain resulting from thermal expansion is reduced by its plastic deformation, and thereby such reduction in the Schottky barrier height caused from the generation of the piezoelectric charge is also prevented.

Furthermore, as the temperature at which Mo undergoes a solid phase reaction with Cu is 1000° C. or higher, such a solid phase reaction is hardly caused by a heat treatment at 300 to 400° C., and so it has an effect of well maintaining its fine electrode shape. Here, in this embodiment, explanation is made for such a mode in which Mo is used as a first electrode material 3, but the temperature at which Nb and W undergo a solid phase reaction with Cu is 1000° C. or higher, and thus, they may have a very similar effect. Furthermore, the temperature at which Pd, Pt and Ti, which are all vacuum deposited more easily than Mo, W and Nb, undergo a solid phase reaction with Cu is 500° C. or higher, and so these metals have a similar effect. Furthermore, aluminum (Al) used instead of Au as the second electrode material 4 had a similar effect.

The first electrode material 3 is required to have a thermal coefficient smaller than that of copper (Cu) and be free from any solid phase reaction with copper (Cu) in a heat treatment at 300° C. or higher, and it is desirable that the temperature at which it undergoes the solid phase reaction is 400° C. or higher. Suitable for the second electrode material 4 is a material being superior in electric conductivity to the first electrode material 3 and further having such a property that a thermal expansion coefficient smaller than the thermal expansion coefficient of the copper (Cu) or that an internal stress generated by thermal expansion in the first electrode material 3 and the second electrode material 4 is reduced by its plastic deformation.

For the heat treatment for increasing the barrier height, the temperature is to be 300° C. or higher, and it is preferable to set such an upper limit to the temperature that it is set at 650° C. or lower, which is lower than the temperature at which a solid phase reaction with Cu occurs and is corresponding to a temperature for forming the ohmic contact in the production process. Accordingly, it is preferable that for the heat treatment for improving the barrier height, the temperature is set to be 300° C. or higher and 650° C. or lower.

### EXAMPLE 4

This embodiment will be explained below by referring to a specific example. As a nitride semiconductor layer 1, an AlN buffer layer having a thickness of 4 nm and an n type GaN layer having a donor concentration of 10¹⁷ atoms·cm⁻³ and a thickness of 2000 nm were formed on a high-resistance SiC substrate. Furthermore, Ti and Al were successively vacuum deposited as an ohmic electrode for the nitride semiconductor. Thereafter, a heat treatment was carried out at 650° C. in a nitrogen atmosphere to form an ohmic contact.

After that, copper (Cu) 2 was vacuum deposited in a thickness of 200 nm, and molybdenum (Mo) in a thickness of 100 nm as a first electrode material layer 3 and gold (Au) in a thickness of 300 nm as a second electrode material layer 4 were subsequently deposited by electron beam deposition, and lifted off to form a Schottky electrode according to the present invention. The Schottky electrode could also be formed by means of sputtering. The barrier height was estimated based on its current/voltage characteristics of the Schottky diode in forward bias. The results are summarized in Table 3.

[Table 3]

TABLE 3

| | Electrode materials | Barrier | | |
|---|---|---|---|---|
| | (heat treatment | heights | | Thickness |
| Experiments | temperature) | (eV) | n values | (nm) |
| 13 | Cu/Mo/Au (300° C.) | 1.24 | 1.16 | 200/100/300 |
| 14 | Cu/Mo/Au (400° C.) | 1.29 | 1.16 | 200/100/300 |

By heat-treating the Schottky diode at 300° C. or 400° C., the barrier height was further increased from 1.1 eV, i.e. the value measured before the heat treatment, to 1.24 eV or 1.29 eV, respectively. The Schottky electrode was formed thickly with copper (Cu) layer in a thickness of 200 nm, molybdenum (Mo) layer in a thickness of 100 nm and gold (Au) layer in a thickness of 300 nm, but as for the barrier height, the same effect as that observed for the thin Cu single layer having a thickness of 200 nm was maintained in this case. A decrease in the barrier height resulting from a heat treatment, which was a problem found out in the case of using the Cu single layer having an increased thickness of 400 nm for reducing the resistance of the electrode, did not occur in this case.

A Schottky electrode having a high barrier height and a low resistance was obtained by forming the Schottky electrode thickly with copper (Cu) layer in a thickness of 200 nm, molybdenum (Mo) layer in a thickness of 100 nm and gold (Au) layer in a thickness of 300 nm.

Here, molybdenum (Mo) was used as the first electrode material 3, but when tungsten (W) and niobium (Nb) were used in place of molybdenum (Mo) as the first electrode material 3, a similar effect was obtained. For Schottky diodes using these three metals, performances were by no means deteriorated by heat treatment at 600° C. For palladium (Pd), platinum (Pt) or titanium (Ti) which are easily deposited by electron beam deposition, a similar effect was obtained by a heat treatment at 300° C. or 400° C. Furthermore, a similar effect was obtained when aluminum (Al) was used as the second electrode material 4.

For the heat treatment for increasing the barrier height, the temperature is 300° C. or higher, and it is preferable to set such an upper limit to the temperature that it is set at 650° C. or lower, which is corresponding to a temperature for forming the ohmic contact in the production process.

### EXAMPLE 5

A nitride semiconductor electric field effect transistor using the Schottky electrode according to this embodiment as a gate electrode 8 is illustrated in FIG. 4. As a nitride semiconductor operation layer 6, an AlN buffer layer having a thickness of 4 nm, an undoped GaN layer having a thickness of 2000 nm and an AlGaN layer (Al composition ratio: 0.25, thickness: 30 nm) were formed on a high-resistance Si substrate. As a source electrode 7 and a drain electrode 9, Ti and Al were successively deposited. Thereafter, a heat treatment was carried out at 650° C. in a nitrogen atmosphere to form an ohmic contact.

After that, copper (Cu) 2 was deposited in a thickness of 200 nm, and molybdenum (Mo) in a thickness of 100 nm as a first electrode material and gold (Au) in a thickness of 300 nm as a second electrode material were subsequently deposited by electron beam deposition and lifted off to form a gate electrode 8 according to the present invention. The Schottky electrode could also be formed by means of sputtering.

By using the Schottky electrode as the gate electrode 8, an electric field effect transistor having a low gate resistance because of the increased thickness of the electrode and having a reduced reverse leak current could be formed. A gain of 23 dB higher than that of example and a high output density of 10 W/mm (per gate width) equal to that of Example 3 could be obtained with a 60 V operation at an operation frequency of 20 GHz by a high-output device having a gate length of 1 micron and a gate width of 1 mm.

The present invention has been explained specifically based on examples, but the present invention is not limited to the modes of the examples, and may be modified in a variety of ways without departing from the concept thereof as a matter of course.

1. A Schottky electrode for a nitride semiconductor device characterized in that
said Schottky electrode has a layered structure that comprises a copper (Cu) layer being in contact with a nitride semiconductor and a first electrode material layer formed on said copper (Cu) layer as an upper layer thereof, and
the temperature at which said first electrode material starts to undergo a solid phase reaction with copper (Cu) is 400° C. or higher.

2. A Schottky electrode for a nitride semiconductor device as claimed in claim 1, wherein the thermal expansion coefficient of said first electrode material is smaller than the thermal expansion coefficient of copper (Cu).

3. A Schottky electrode for a nitride semiconductor device as claimed in claim 1, wherein a second electrode material layer is further formed on said first electrode material layer,
the thermal expansion coefficients of said first electrode material and second electrode material are smaller than the thermal expansion coefficient of copper (Cu), or an internal stress caused by thermal expansion in said first electrode material layer and second electrode material layer is reduced by plastic deformation thereof, and
further, the resistivity of said second electrode material is lower than the resistivity of the first electrode material.

4. A Schottky electrode for a nitride semiconductor device as claimed in any one of claims 1, wherein said first electrode material is molybdenum, tungsten, niobium, palladium, platinum or titanium.

5. A Schottky electrode for a nitride semiconductor device as claimed in claim 3, wherein said second electrode material is gold or aluminum.

6. A nitride semiconductor electric field effect transistor characterized in that the Schottky electrode for a nitride semiconductor device as claimed in claim 1 is used as a gate electrode thereof.

7. A process for production of a Schottky electrode for a nitride semiconductor device characterized by comprising:
a step of forming a metal layer in which at least a copper (Cu) layer is formed on a nitride semiconductor layer; and
a step of carrying out a heat treatment at a temperature of 300° C. or higher and 650° C. or lower.

8. A process for production of a Schottky electrode for a nitride semiconductor device as claimed in claim 7, wherein said step of forming a metal layer comprises the sub-steps of:
forming the copper (Cu) layer; and
forming a first electrode material layer.

9. A process for production of a Schottky electrode for a nitride semiconductor device as claimed in claim 7, wherein said metal layer forming step comprises the sub-steps of:
forming the copper (Cu) layer;
forming a first electrode material layer; and
forming a second electrode material layer.
